(19) United States
(12) Patent Application Publication
(10) Pub. No.: US 2008/0217673 A1
(43) Pub. Date: Sep. 11, 2008

(54) SEMICONDUCTOR DEVICE AND METHOD FOR MANUFACTURING THE SAME

(75) Inventors: Takayuki Maruyama, Aizuwakamatsu-shi (JP); Yukio Hayakawa, Aizuwakamatsu-shi (JP); Hiroyuki Nansei, Aizuwakamatsu-shi (JP)

Correspondence Address: INGRASSIA FISHER & LORENZ, P.C., 7010 E. COCHISE ROAD, SCOTTSDALE, AZ, 85253, US

(73) Assignee: Spansion LLC, Sunnyvale, CA (US)

(21) Appl. No.: 12/026,421

(22) Filed: Feb. 5, 2008

(30) Foreign Application Priority Data
Feb. 5, 2007 (JP) JP 2007-025336

(51) Int. Cl. H01L 29/94; H01L 21/02; H01L 21/336

(52) U.S. Cl. 257/306; 257/531; 438/261; 257/E21.022

(57) ABSTRACT

A semiconductor device includes a stack structure in which multiple channel layers are stacked on a substrate so as to be sandwiched between bit line layers, a gate electrode that is provided to the side of the lateral surface of an interior of a groove portion formed within the stack structure, and a charge storage layer that is provided between the gate electrode and the channel layer.

### TECHNICAL FIELD

The present invention relates to a semiconductor device and a method for manufacturing the same, and more particularly, to a semiconductor device that has an ONO film on lateral surfaces of groove portions formed in a semiconductor substrate, and a method for manufacturing the same.

### BACKGROUND OF THE INVENTION

Nonvolatile memories, which are semiconductor devices permitting rewriting of data, have come into widespread use in recent years. Typical nonvolatile memories are flash memories, in which transistors that constitute memory cells have a floating gate or an oxide-nitride-oxide (ONO) film, which is termed a charge storage layer. Data is memorized by storing electrical charges in the charge storage layer.

Further, flash memories with various types of memory cell structure have been developed in order to achieve high memory capacity. U.S. Pat. No. 6,011,725 (hereinafter simply referred to as Document 1) discloses a NOR type flash memory (related art example 1), in which two charge storage regions can be formed in an ONO film of a single memory cell. Japanese Patent Application No. 2003-508914 (Document 2) discloses a flash memory (related art example 2) in which, at corner portions and bottom parts of convexities between groove portions formed in a semiconductor substrate, there are formed bit lines that run in the longitudinal direction of the groove portions and are constituted of diffused layers, and word lines that run in the width direction of the groove portions.

In related art example 1, the memory cells are formed in the plane of the semiconductor substrate, and the memory capacity is not adequate. In related art example 2, the groove portions are formed in the semiconductor substrate, and high memory capacity is achieved by using the floating gates or the ONO films on the groove portion lateral surfaces as the charge storage layers. However, the bit lines are, for example, formed to be separated in the width direction of the groove portions, and the manufacturing method for such is complex.

### SUMMARY OF THE INVENTION

The present invention has been made in view of the above-mentioned circumstances and provides a semiconductor device enabling high memory capacity, and a method for manufacturing thereof.

According to an aspect of the present invention is a semiconductor device that has: a stack structure in which multiple channel layers are stacked on a substrate so as to be sandwiched between bit line layers; gate electrodes that are provided to the sides of the lateral surfaces of the interiors of groove portions formed within such stack structure; and a charge storage layer that is provided between the gate electrodes and the channel layers. According to this aspect of the invention, multiple charge storage regions can be formed in the charge storage layer provided to the sides of the lateral surfaces of the interior of the groove portion, and therefore the memory capacity density can be enhanced.

According to another aspect of the present invention, there is provided a semiconductor device that has: multiple semiconductor layers which have source drain regions and channel regions disposed alternately in the lateral direction, which are stacked in the longitudinal direction so that the source drain regions and the channel regions are superposed, and which are insulated from one another; gate electrodes that are provided to the sides of the channel regions at the lateral surfaces of the interiors of groove portions that are formed in the multiple semiconductor layers and extend in the lateral direction; charge storage layers that are provided between the channel regions and the gate electrodes; and insulating layers that are provided to the sides of the source drain regions at the lateral surfaces of the interiors of the groove portion. According to this aspect of the invention, the memory capacity density can be enhanced.

According to a further aspect of the present invention, there is provided a semiconductor device that has: a first bit line layer that is provided over a substrate; a channel layer containing polysilicon that is provided over the first bit line layer; a second bit line layer that is provided over the channel layer; a gate electrode that is provided to the sides of the lateral surfaces of an interior of a groove portion formed in the channel layer; and a charge storage layer that is provided between the gate electrode and the channel layer. According to this aspect of the invention, a substrate other than a semiconductor substrate can be used, and therefore the manufacturing costs can be reduced.

According to a still further aspect of the present invention, there is provided a semiconductor device manufacturing method that includes: stacking, over a structure, multiple channel layers sandwiched between bit line layers above and below; forming groove portions in the multiple channel layers so as to reach as far as a lower surface of the lowermost channel layer; forming charge storage layers to the sides of the lateral surfaces of the interiors of the groove portion; and forming gate electrodes inside the groove portions. According to this aspect of the invention, multiple charge storage regions are formed in the charge storage layers provided to the sides of the lateral surfaces of the interiors of the groove portion, and therefore the memory capacity density can be enhanced.

According to a yet further aspect of the present invention, there is provided a semiconductor device manufacturing method that involves: stacking multiple semiconductor layers so as to be insulated from one another; forming source drain regions and channel regions alternately in the lateral direction inside the semiconductor layers; forming groove portions in the multiple semiconductor layers so as to reach as far as a lower surface of the lowermost semiconductor layer; forming charge storage layers to the sides of the lateral surfaces of the interiors of the groove portion; and forming gate electrodes inside the groove portions. According to this aspect of the invention, the memory capacity density can be enhanced.

### BRIEF DESCRIPTION OF THE DRAWINGS

FIGS. 1(a) through 1(c) are cross-sectional views illustrating manufacturing processes for a flash memory of a first embodiment of the invention;

FIG. 2 is a cross-sectional view of the flash memory of the first embodiment;

FIG. 3 is a cross-sectional view of a flash memory of a second embodiment;

FIG. 4 is a cross-sectional view of a flash memory of a third embodiment;

FIG. 5 is a cross-sectional perspective view of a flash memory of a fourth embodiment;

FIG. 6 is a circuit diagram of a flash memory of the fourth embodiment;

FIGS. 7(a) and 7(b) are cross-sectional perspective views illustrating a first half of manufacturing processes for the flash memory of the fourth embodiment;

FIGS. 8(a) and 8(b) are cross-sectional perspective views further illustrating a second half of manufacturing processes for the flash memory of the fourth embodiment;

FIG. 9 is a cross-sectional perspective view of a flash memory of a fifth embodiment;

FIG. 10 is a circuit diagram of the flash memory of the fifth embodiment;

FIGS. 11(a) through 11(d) are cross-sectional views illustrating manufacturing processes for a flash memory of a sixth embodiment;

FIG. 12 is a cross-sectional view of the flash memory of the sixth embodiment;

FIG. 13 is a circuit diagram of a flash memory of a seventh embodiment;

FIGS. 14(a) and 14(b) are cross-sectional perspective views of the flash memory of the seventh embodiment; and

FIGS. 15(a) through 15(c) are cross-sectional perspective views illustrating manufacturing processes for the flash memory of the seventh embodiment.

### DETAILED DESCRIPTION

Embodiments of the invention will now be described using the accompanying drawings.

### First Embodiment

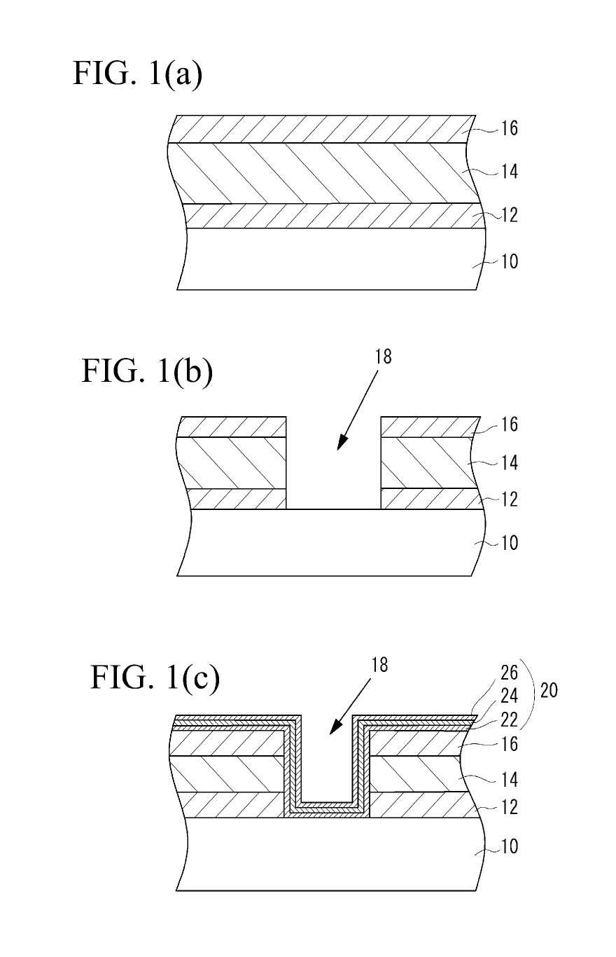

FIGS. 1(a) to 1(c) are cross-sectional views illustrating a flash memory manufacturing method of a first embodiment of the present invention. As shown in FIG. 1(a), on a silicon substrate 10, or on a boro-phospho silicate glass (BPSG) or like insulating layer over a substrate, there are formed using, for example, a CVD method: a bit line layer 12 made of polysilicon of a thickness of 0.16 μm and doped into N-type at 1×10²¹ cm⁻³; a channel layer 14 made of polysilicon of a thickness of 0.2 μm that is non-doped, or else doped into P-type at 1×10¹⁷ cm⁻³; and a bit line layer 16 made of polysilicon of a thickness of 0.16 μm and doped into N-type at 1×10¹⁷ cm⁻³. The bit line layer 12 may alternatively be formed on the silicon substrate 10 via implantation with ions of arsenic (As) or the like.

A groove portion 18 is then formed so as to reach as far as the substrate 10, as shown in FIG. 1(b). Then as shown in FIG. 1(c), there are formed on the lateral surfaces of the groove portion 18, or in other words, on the lateral surfaces of the channel layer 14 and the bit line layers 12 and 16: a tunnel oxide film 22 constituted of a silicon oxide film, a trap layer 24 constituted of a silicon nitride film, and a top oxide film 26 constituted of a silicon oxide film. Thereby, an ONO film 20 composed of the tunnel oxide film 22, the trap layer 24 and the top oxide film 26 is formed.

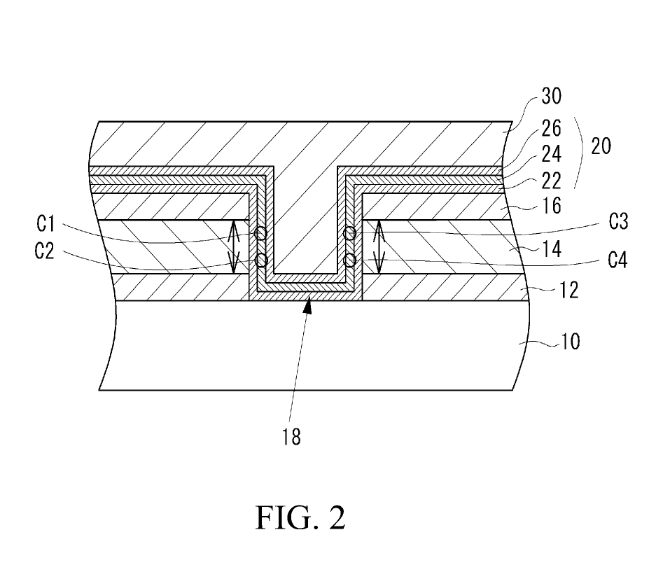

As shown in FIG. 2, a gate electrode 30 made of polysilicon is then formed so as to fill in the groove portion 18 and cover the ONO film 20. The flash memory thus formed has a polysilicon stack composed of the bit line layer 12 (first bit line layer) provided over the substrate 10, the channel layer 14 formed over the bit line layer 12, and the bit line layer 16 (second bit line layer) provided over the channel layer 14. There is the gate electrode 30 provided to the sides of the lateral surfaces of the interior of the groove portion 18 formed in the stack that includes the channel layer 14, and between the gate electrode 30 and the channel layer 14 there is provided the trap layer 24 (charge storage layer). As FIG. 2 shows, vertical directions in the channel layer 14, which is sandwiched between the bit line layers 12 and 16 on either side of the groove portion 18, constitute channels (indicated by the two-headed arrows in FIG. 2). Inside the trap layers 24 lying vertically relative to the channel layer 14, four charge storage regions C1 to C4 can be formed in two pairs. Further, since the channel layer 14 is polysilicon, the substrate 10 need not be polysilicon, so that for example it would be possible to form a BPSG layer on an insulating substrate and to form the structure of the first embodiment thereover. Thereby, the manufacturing costs could be reduced.

### Second Embodiment

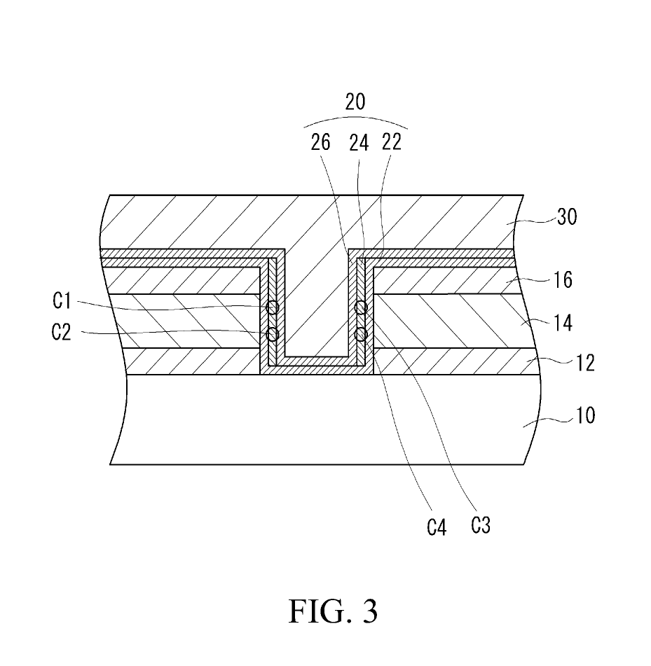

The trap layer 24 may, as shown in FIG. 3, be formed to the sides of the groove portion 18 without being formed over the bottom of the groove portion 18 nor over the bit line layer 16. That is, the structure may be such that the trap layer 24 formed to the sides of the groove portion 18 is separate on each side. Thereby it is be possible to make the groove portion 18 narrower without the charge storage regions on the two sides of the groove portion 18 (for example, C2 and C4) overlapping each other.

### Third Embodiment

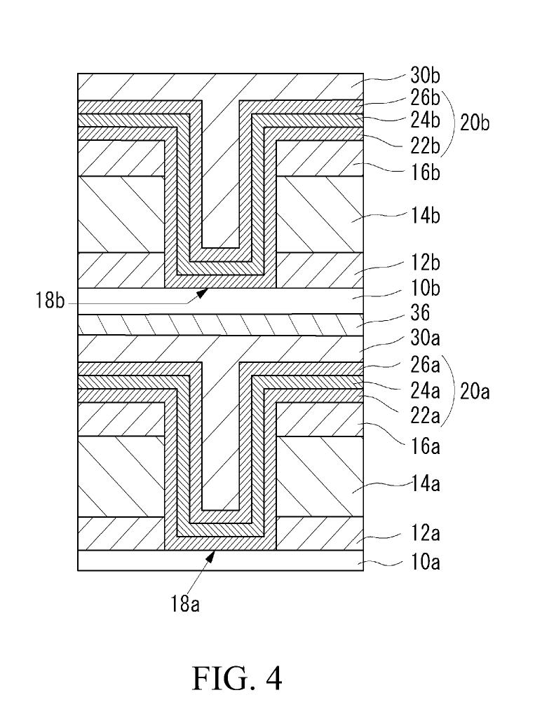

The memory cell of the first embodiment may, as FIG. 4 shows, be stacked in the longitudinal direction. In that case (third embodiment), a bit line layer 12a, a channel layer 14a and a bit line layer 16a are provided stacked as shown in FIG. 4. In such stack there is formed a groove portion 18a, and on the lateral surfaces of the groove portion 18a there is formed an ONO film 20a. A gate electrode 30a is formed so as to fill in the groove portion 18a. Over the gate electrode 30a there are formed, for instance, an interlayer insulating film and a wiring layer 36. Thereover, a BPSG layer 10b is formed and then a second memory cell is stacked in the same manner as the first. The structure of the second memory cell is the same as that of the first and a description thereof is therefore omitted.

Since the semiconductor device of the first embodiment has the channel layer 14 made of polysilicon, the memory cells thereof could be stacked in the manner of the third embodiment. Thereby, the memory density could be raised to a high level.

### Fourth Embodiment

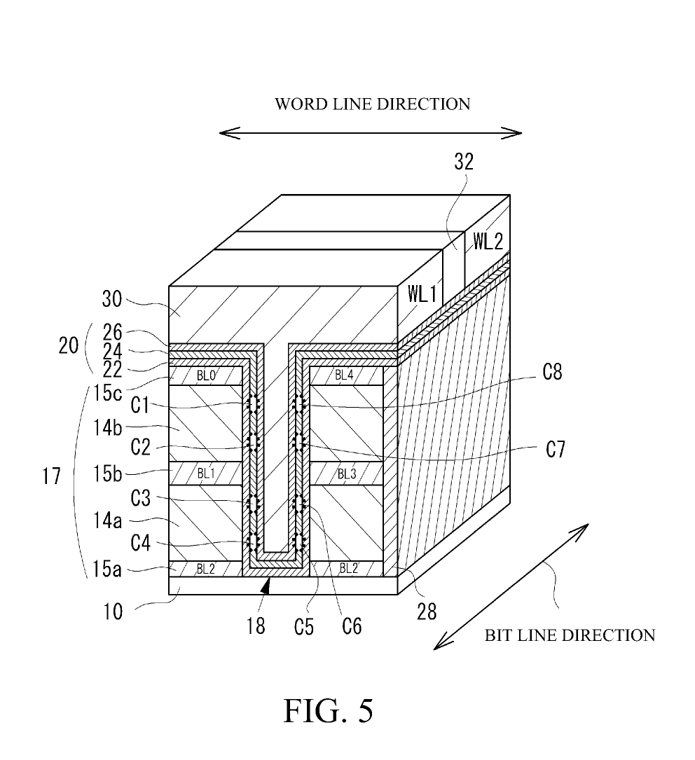

FIG. 5 is a perspective view of a memory cell in a flash memory of a fourth embodiment of the invention. A bit line layer 15a, a channel layer 14a, a bit line layer 15b, a channel layer 14b and a bit line layer 15c made of polysilicon are stacked on the silicon substrate 10 (or on an insulating layer of BPSG or the like over the substrate). In other words, there is a stack structure 17 such that multiple channel layers 14 are stacked, sandwiched between bit line layers 15 above and below, on the substrate 10. In such stack structure 17 made of polysilicon there is formed a groove portion 18. An ONO film 20 is provided on the lateral surfaces of the groove portion 18. The gate electrode 30 is provided so as to fill in the groove portion 18 and cover the ONO film 20.

The stack is provided with an element separating layer 28 constituted of a silicon oxide film, and is electrically separated by the element separating layer 28 from the memory cell (not shown in the drawings) lying in the word line direction indicated in FIG. 5. The gate electrodes 30 of the multiple memory cells (of which only one is shown in FIG. 5) disposed in the direction of the width of the groove portion 18 (the word line direction) are connected over the stack structure and form word lines WL1 and WL2. Each gate electrode 30 is electrically separated (into word lines WL1 and WL2) by an insulating layer 32 that runs in the width direction of the groove portion 18.

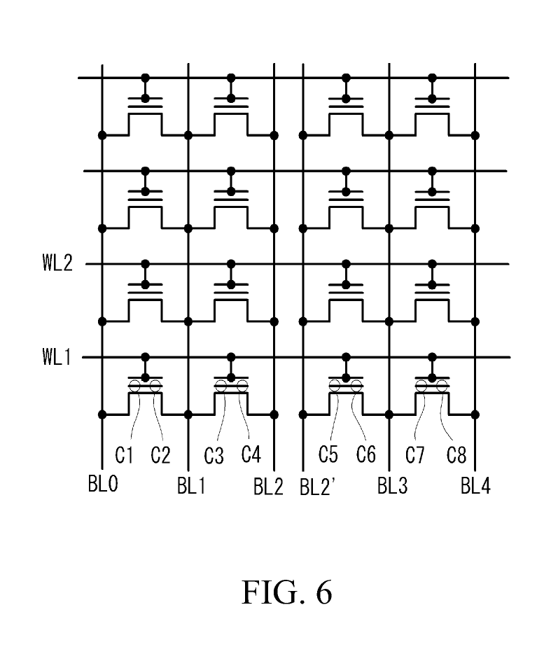

FIG. 6 is a circuit diagram of the memory cell of the fourth embodiment. As FIG. 6 shows, the fourth embodiment constitutes a NOR type memory cell. Bit lines BL0 to BL4 in FIG. 6 correspond to the bit lines BL0 to BL2, and BL2′ to BL4, of the bit line layers 15a to 15c in FIG. 5, the bit line layers 15a, 15b and 15c running in the direction of the bit line direction arrow in FIG. 5 constituting the bit lines BL0 to BL2 and BL2′ to BL4. Also, the word lines WL1 and WL2 in FIG. 6 correspond to the word lines WL1, WL2 to which the gate electrode 30 is connected in FIG. 5. The charge storage regions C1 to C8 of the memory cell in FIG. 6 correspond to the charge storage regions C1 to C8 formed in the trap layer 24 in FIG. 5.

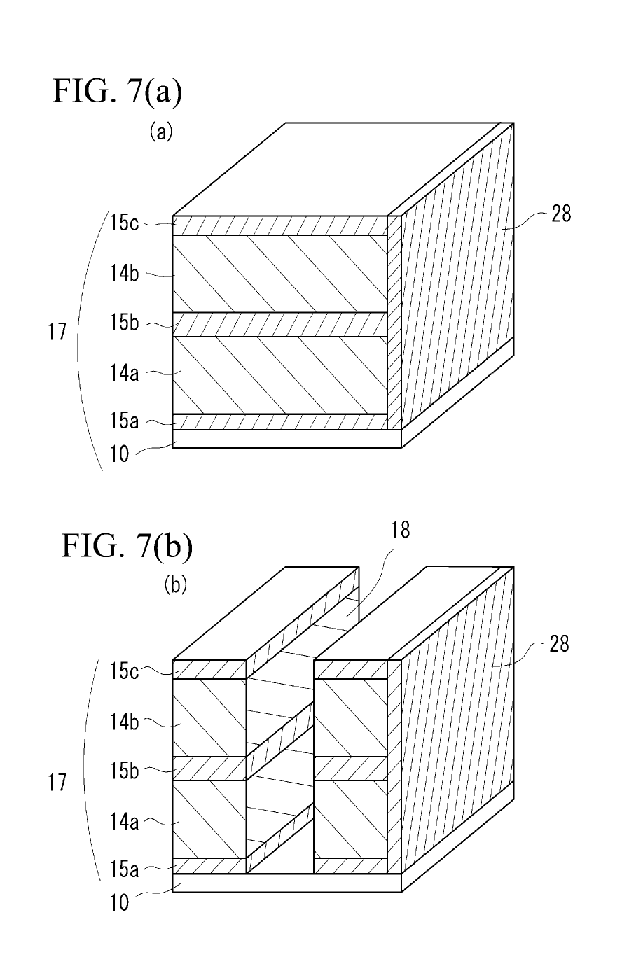

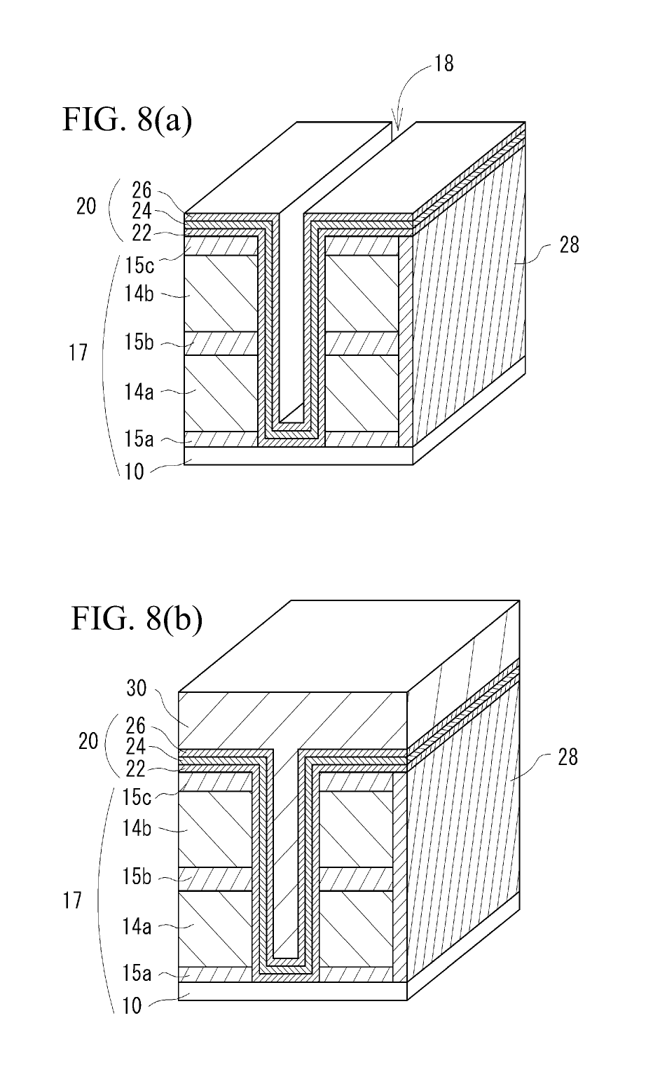

The method for manufacturing the flash memory of the fourth embodiment will now be described using FIGS. 7 (a) to 8 (b). As shown in FIG. 7 (a), the bit line layers 15a, 15b and 15c, and the channel layers 14a and 14b, are stacked on the silicon substrate 10 (or on an insulating layer of BPSG or the like over the substrate), using the CVD method. In other words, multiple channel layers 14 are stacked, sandwiched between the bit line layers 15 above and below, on the substrate 10 to form the stack structure 17. Using a shallow trench isolation (STI) method, the element separating layers 28 made of silicon oxide film are formed so as to reach to the substrate 10. As shown in FIG. 7 (b), the groove portion 18 that reaches as far as the substrate 10 is formed between the element separating layers 28. That is, the groove portion 18 is formed in the stacked channel layers 14.

As shown in FIG. 8 (a), on the lateral surfaces of the groove portion 18, or in other words on the lateral surfaces of the channel layers 14, there are formed, to serve as the ONO film 20, the tunnel oxide film 22 formed by a silicon oxide film, the trap layer 24 formed by a silicon nitride film, and the top oxide film 26 constituted of a silicon oxide film. As shown in FIG. 8 (b), the gate electrode 30 made of, for example, polysilicon is formed over the stack structure 17 so as to fill in the groove portion 18. The gate electrode 30 is formed on the lateral surfaces of the ONO film 20 inside the groove portion 18. As shown in FIG. 5, the gate electrode 30 is separated in the bit line direction to form the insulating layer 32. Thereby, multiple gate electrodes 30 (word lines WL1 and WL2) are formed. After that, there are formed an interlayer insulating film, a wiring layer and so forth, not shown in the drawings, whereupon the flash memory is complete.

According to the fourth embodiment, the stack structure 17 is provided in which the multiple channel layers 14 are stacked, sandwiched between the bit line layers 15 above and below, on the substrate 10. The gate electrode 30 is provided to the sides of the lateral surfaces of the interior of the groove portion 18 formed in the channel layers 14 within the stack structure 17. Between the gate electrode 30 and the channel layers 14 there is placed the trap layer 24 that is a charge storage layer formed by an insulator. Thus with the fourth embodiment, when there are two channel layers 14, there can be four charge storage regions on each side of the groove portion 18, making eight on the two sides. In this way the memory capacity density can be enhanced. As compared to the third embodiment in particular, the groove portion 18 is formed continuously in the channel layers 14a and 14b, which will enable the use of thin films in the longitudinal direction and simplification of the manufacturing process. Also, the channel layers 14 are not limited to the quantity of two, and could be multiple.

Multiple gate electrodes 30 are provided in the word line direction (width direction of the groove portion 18) indicated in FIG. 5. This enables a multiple quantity of the memory cell of FIG. 6 to be disposed in the word line direction.

The multiple gate electrodes 30 disposed in the word line direction (width direction of the groove portion 18) may be connected above the stack structure 17 and form word lines WL1, WL2. This will enable a multiple quantity of the memory cell of FIG. 6 to be disposed in the word line direction.

The word lines WL1 and WL2 are provided in multiple quantity in the bit line direction (direction in which the groove portion 18 extends) and are electrically separated from each other. Thus, multiple word lines can be provided in the bit line direction.

Since the channel layers 14 contain polysilicon, it is possible to stack a multiple quantity of the channel layers 14 in a simple manner as shown in FIG. 5. Also, the bit line layer 15b between the adjacent channel layers 14a and 14b among the stacked channel layers is shared, and can be used for both the channel layer 14a and the channel layer 14b. Thereby, the number of layers in the stack structure 17 can be reduced.

### Fifth Embodiment

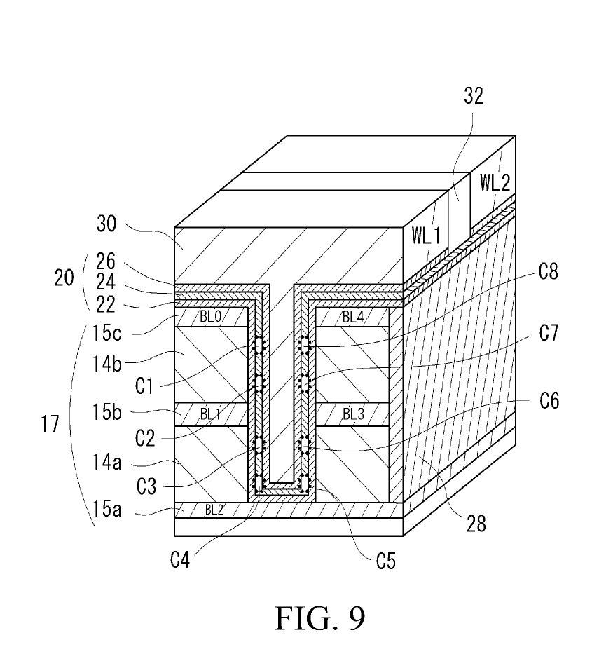

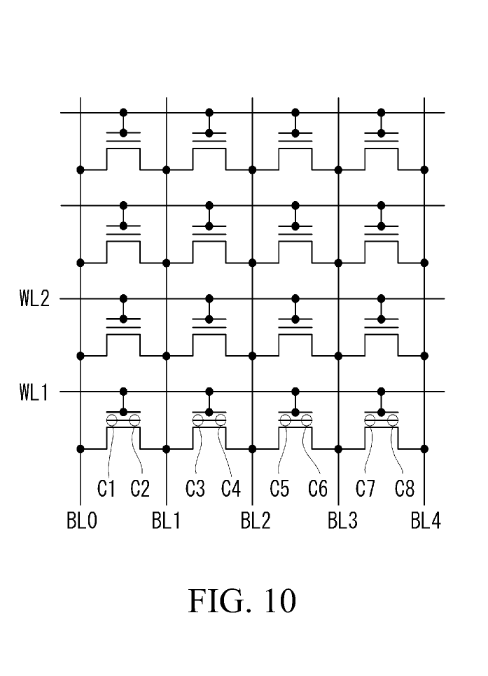

As FIG. 9 shows, in a fifth embodiment, as opposed to the fourth embodiment, the groove portion 18 is formed so as to reach as far as the lower surface of the lowermost channel layer 14a of the stack structure 17, and is not formed in the lowermost bit line layer 15a. Because of this, the bit line layer 15a can be shared by the channel layer 14a on its right and left. FIG. 10 is a circuit diagram of the fifth embodiment. As opposed to the circuit diagram of the fourth embodiment in FIG. 6, the bit lines BL2 and BL2′ are made into a common bit line BL2. In other respects the fifth embodiment has the same configuration as the fourth embodiment and the same members with the same reference numerals. A description thereof is therefore omitted.

### Sixth Embodiment

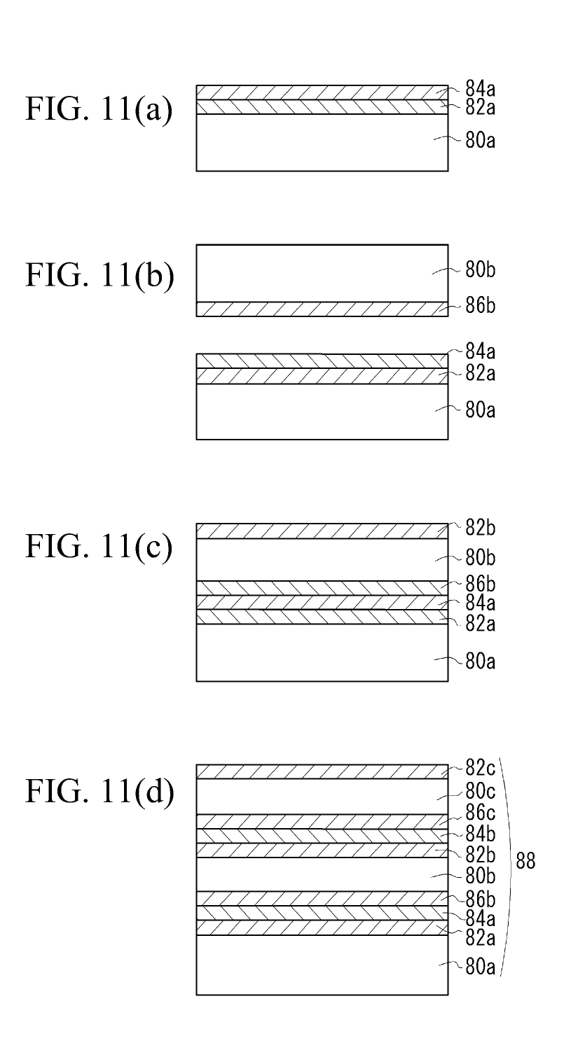

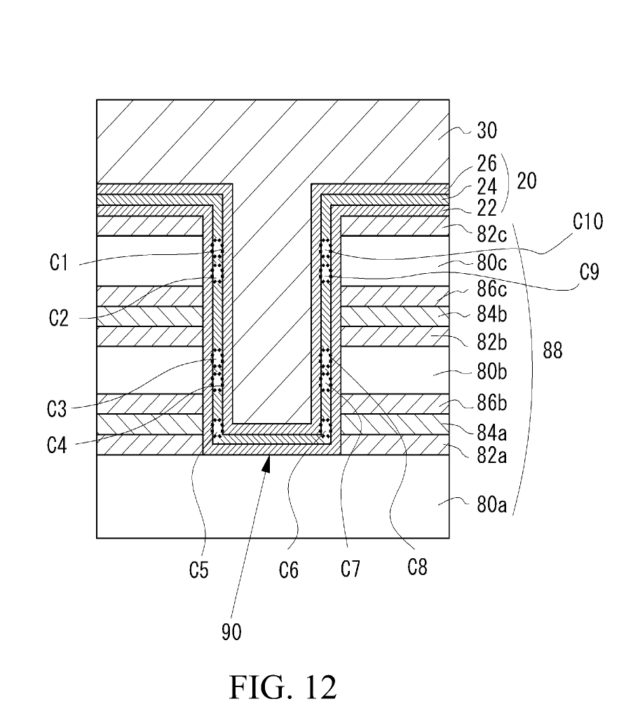

A sixth embodiment represents the case where silicon layers are used for the channel layers. The method for manufacturing a flash memory of the sixth embodiment will now be described using FIGS. 11(a) to 12. As shown in FIG. 11(a), a bit line layer 82a made of N-type polysilicon is formed on a P-type silicon substrate 80a, using the CVD method. An insulating layer 84a formed by a silicon oxide film is formed over the bit line layer 82a. As shown in FIG. 11(b), a bit line layer 86b made of N-type polysilicon is formed on a substrate 80b. As shown in FIG. 11(c), the insulating layer 84a and the bit line layer 86b are stuck together. The substrate 80b is ground, then a bit line layer 82b is formed over the substrate 80b. In a similar manner, a bit line layer 86c, a substrate 80c and a bit line layer 84c are formed as shown in FIG. 11(d). In this way there is formed a stack structure 88 in which the substrates 80a, 80b and 80c (also termed “channel layers” below) are stacked. The bit line layers 82a, 82b, 82c, 86b, 86c may for example be formed by the method of implanting ions of, for example, arsenic (As) into the substrates 80a, 80b, 80c.

As shown in FIG. 12, a groove portion 90 that reaches to the substrate 80a is formed in the stack structure 88. The ONO film 20 is formed on the lateral surfaces of the groove portion 90. The gate electrode 30 is formed over the ONO film 20 so as to fill in the groove portion 90. With the sixth embodiment, ten charge storage regions C1 to C10 can be provided. Further, an insulating layer 84b is provided between the bit line layers 82b, 86c between the mutually adjacent channel layers 80b, 80c among the stacked channel layers. Thus, by sticking multiple silicon substrates 80 together using silicon oxide layers 84, there is formed the stack structure 88 in which the multiple channel layers 80 are stacked. Since the silicon substrates 80 are thereby used as channel layers, the performance can be enhanced compared to the fourth embodiment, in which polysilicon is used for the channel layers 14.

### Seventh Embodiment

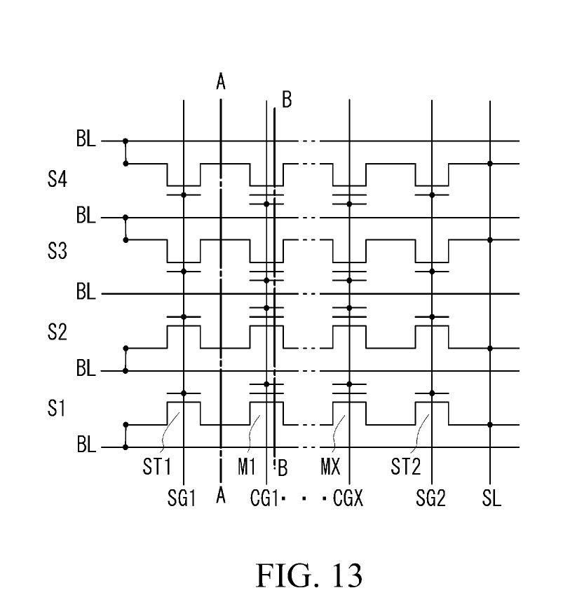

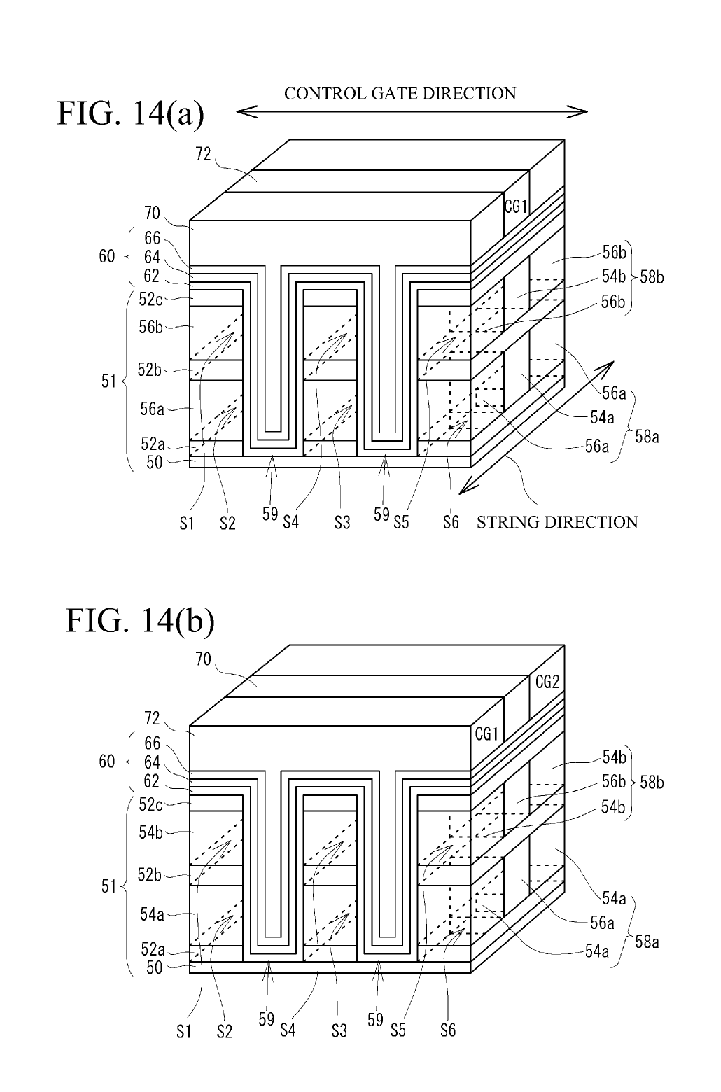

A seventh embodiment represents the case of a NAND type flash memory. FIG. 13 is a circuit diagram of memory cells in the flash memory of the seventh embodiment, and FIGS. 14(a) and 14(b) are perspective views of the memory cells of the seventh embodiment. As FIG. 13 shows, in a string S1, multiple memory cells M1 to MX and selecting transistors ST1, ST2 are connected in parallel. The string S1 of the memory cells M1 to MX is connected via the selecting transistors ST1 and ST2 to bit lines BL and a source line SL. Control gates CG1 to CGX for the memory cells M1 to MX, and selecting gates SG1 and SG2 for the selecting transistors ST1 and ST2, are connected to each of the strings S1 to S4. The example described here has four strings, but embodiments are not limited to this quantity of strings.

FIG. 14(a) is a cross-section corresponding to A-A in FIG. 13, or more precisely, a perspective view showing a cross-section through source drain regions. FIG. 14(b) is a cross-section corresponding to B-B in FIG. 13, or more precisely, a perspective view showing a cross-section through channel regions. As FIGS. 14(a) and 14(b) show, a stack structure 51 is provided in which an insulating layer 52a, a semiconductor layer 58a, an insulating layer 52b, a semiconductor layer 58b and an insulating layer 52c are stacked on a silicon substrate 50 (or on an insulating layer of BPSG or the like over the substrate). This means that the multiple semiconductor layers 58a and 58b are provided insulated from and stacked over each other. The semiconductor layers 58a and 58b have source drain regions 56a, 56b and channel regions 54a, 54b that are disposed alternately in the lateral direction (string direction) relative to the stacking direction. The source drain regions 56a, 56b and the channel regions 54a, 54b of the semiconductor layers 58a and 58b respectively are stacked in the longitudinal direction (that is, the stacking direction) so that the respective regions are superposed.

In the stack structure 51 there are provided groove portions 59 that reach to the substrate 50 and extend in the lateral direction (string direction). On the lateral surfaces of the groove portions 59 there is provided an ONO film 60 composed of a tunnel oxide film 62, a trap layer 64 and a top oxide film 66. Over the ONO film 60, gate electrodes 72 and insulating layers 70 are provided so as to fill in the groove portions 59. The gate electrodes 72 are provided to the sides of the channel regions 54a and 54b at the lateral surfaces of the interiors of the groove portion 59. In other words, the gate electrodes 72 are provided between the channel regions 54a and between the channel regions 54b of two strings. For example, they are provided between the channel regions 54a of strings S2 and S3, and between the channel regions 54b of strings S1 and S4. The insulating layers 70 are provided to the sides of the source drain regions 56a and 56b at the lateral surfaces of the interiors of the groove portion 59. In other words, the insulating layers 70 are provided between the source drain regions 56a and between the source drain regions 56b of two strings. For example, they are provided between the source drain regions 56a of the strings S2 and S3, and between the source drain regions 56b of the strings S1 and S4. Thus, the gate electrodes 72 and the insulating layers 70 are provided alternately in the lateral direction (string direction). Also, the trap layer 64 that is a charge storage layer within the ONO film 60 is provided between the channel regions 54a, 54b and the gate electrodes 72.

According to the seventh embodiment, each memory cell M1 to MX is constituted by the channel regions 54a, 54b provided alternately in the string direction in FIGS. 14(a) and 14(b), together with the source drain regions 56a, 56b at the two sides thereof, and the gate electrode 72 provided to the sides of the channel regions 54a, 54b, plus the ONO film 60 between the gate electrode 72 and the channel regions 54a, 54b. The selecting transistor STI, the memory cells M1 to MX and the selecting transistor ST2 are disposed in the string direction to form strings. FIGS. 14(a) and 14(b) show six strings S1 to S6. Also, the gate electrodes 72, which are electrically separated by the insulating layers 70, constitute the control gates CG1 to CGX and the selecting gates SG1 and SG2. In FIGS. 14(a) and 14(b), control gates CG1 and CG2 are shown lying in the control gate direction. The seventh embodiment described in the foregoing manner is able to provide a NAND type flash memory with high memory capacity density.

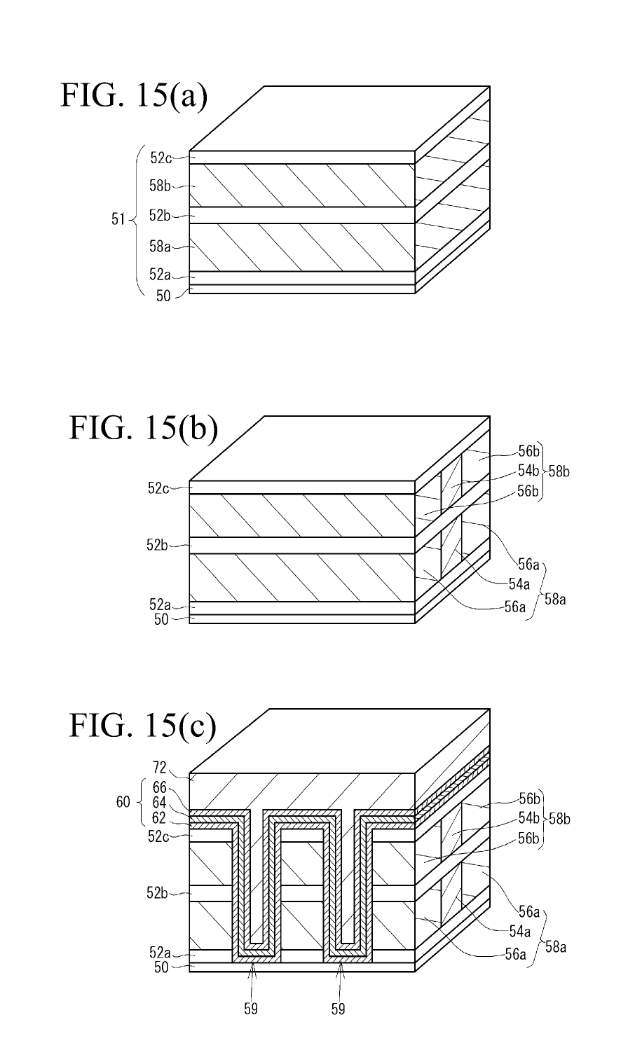

The method for manufacturing the flash memory of the seventh embodiment will now be described using FIGS. 15(a) to 15(c). As shown in FIG. 15(a), the insulating layer 52a formed by a silicon oxide film, the semiconductor layer 58a made of P-type polysilicon, the insulating layer 52b, the semiconductor layer 58b and the insulating layer 52c are formed and stacked on the silicon substrate 50 (or on an insulating layer of BPSG or the like over the substrate). This means that multiple semiconductor layers 58a and 58b are stacked so as to be insulated from each other. The insulating layers 52a to 52c are formed by the CVD method or a thermal oxidation method. The semiconductor layers 58a and 58b are formed by the CVD method.

When the semiconductor layers 58a and 58b are stacked, a portion of each thereof selected arbitrarily is implanted with ions of, for example, arsenic (As), then given heat treatment, as shown in FIG. 15(b). Thereby, the regions within the semiconductor layers 58a and 58b that have been implanted with ions become the source drain regions 56a and 56b, and the regions that are not implanted with ions become the channel regions 54a and 54b. Alternatively, portions selected at will to be the channel regions could be implanted with ions. In this way, the source drain regions 56a and 56b, and the channel regions 54a and 54b, are formed alternately within the semiconductor layers 58a and 58b. Ion implantation may be separately carried out for each layer.

As shown in FIG. 15(c), the groove portions 59 are formed in the multiple semiconductor layers 58a and 58b of the stack structure 51 so as to reach as far as the lower surface of the lowermost semiconductor layer 58a. On the lateral and bottom surfaces of the groove portions 59 and over the top of the stack structure 51 there are formed, to serve as the ONO film 60, the tunnel oxide film 62 formed by a silicon oxide film, the trap layer 64 formed by a silicon nitride film, and the top oxide film 66 formed by a silicon oxide film. This means that the trap layer 64 is formed to the sides of the interiors of the groove portion 59. The gate electrode 72 made of polysilicon is formed over the stack structure 51 so as to fill in the spaces between the lateral surfaces of the ONO film 60 inside the groove portions 59. The gate electrodes 72 are formed over the stack structures 51 so as to be disposed in the direction of the width of the groove portions 59 and to be connected.

The insulating layer 70 that fills in the groove portions 59 and electrically separates the gate electrode 72 is formed to the sides of the source drain regions 56a, 56b of the groove portions 59, as shown in FIG. 14(a). Thereby, the gate electrode 72 is separated in the string direction, and multiple gate electrodes 72 (SG1, CG1 to CGX, SG2) are formed. After that, an interlayer insulating film and wiring layer are formed, whereupon the flash memory of the seventh embodiment is complete. In the seventh embodiment also, the quantity of the semiconductor layers 58a, 58b may be two or more.

Also, in the seventh embodiment the semiconductor layers 58a, 58b, along with the ONO film 60 and the gate electrode 72 on both sides thereof in FIG. 14 (b), constitute the memory cell. That is, the same data is stored in the symmetrical charge storage regions of the ONO film 60 on both sides of, for example, the string S3. However, it would also be possible to have the semiconductor layer 58a constitute the memory cell individually with the ONO film 60 and the gate electrode 72 on each side thereof.

Moreover, although in the first to seventh embodiments the charge storage layer is described as a silicon nitride layer by way of example, it is not limited to this material. Preferably it will be a layer formed by an insulator that stores electric charge, because electric charge does not move in an insulator and therefore it will be easy to form many charge storage regions and raise the memory density. Also, the channel layers and semiconductor layers are not limited to monocrystal silicon or polysilicon. Other materials could be used therefor. Where polysilicon is used, amorphous silicon will be contained in the polysilicon.

Finally, various aspects of the present invention are summarized below.

According to an aspect of the present invention is a semiconductor device that has: a stack structure in which multiple channel layers are stacked on a substrate so as to be sandwiched between bit line layers; gate electrodes that are provided to the sides of the lateral surfaces of the interiors of groove portions formed within such stack structure; and a charge storage layer that is provided between the gate electrodes and the channel layers. According to this aspect of the invention, multiple charge storage regions can be formed in the charge storage layer provided to the sides of the lateral surfaces of the interior of the groove portion, and therefore the memory capacity density can be enhanced.

In the above configuration, the groove portions may be formed to reach as far as the lower surface of the lowermost channel layer of the stack structure.

In the above configuration, multiple word lines may be provided over the stack structure and which are each connected to one of the multiple gate electrodes disposed in the width direction of the groove portions. In that case, multiple memory cells can be disposed in the width direction of the groove portions.

In the above configuration, the multiple word lines may be electrically separated from each other. In that case, multiple memory cells can be disposed in the direction in which the groove portions extend.

In the above configuration, the multiple channel layers may contain polysilicon. In that case, the channel layers can be stacked in a simple manner.

In the above configuration, the bit line layers between the channel layers that are adjacent to each other among the multiple channel layers may be shared. In that case, the number of layers in the stack structure can be reduced.

In the above configuration, insulating layers may be provided between the bit line layers between the channel layers that are adjacent to each other among the multiple channel layers.

In the above configuration, the charge storage layers may be composed of silicon nitride film sandwiched between silicon oxide films.

According to another aspect of the present invention, there is provided a semiconductor device that has: multiple semiconductor layers which have source drain regions and channel regions disposed alternately in the lateral direction, which are stacked in the longitudinal direction so that the source drain regions and the channel regions are superposed, and which are insulated from one another; gate electrodes that are provided to the sides of the channel regions at the lateral surfaces of the interiors of groove portions that are formed in the multiple semiconductor layers and extend in the lateral direction; charge storage layers that are provided between the channel regions and the gate electrodes; and insulating layers that are provided to the sides of the source drain regions at the lateral surfaces of the interiors of the groove portion. According to this aspect of the invention, the memory capacity density can be enhanced.

In the above configuration, the source drain regions and the channel regions disposed alternately in the lateral direction may constitute NAND cells. In that case it will be possible to enhance the memory capacity density of a NAND type nonvolatile memory.

In the above configuration, the semiconductor layers may contain polysilicon. In that case, the semiconductor layers can be stacked in a simple manner.

A further aspect of the present invention is a semiconductor device that has: a first bit line layer that is provided over a substrate; a channel layer containing polysilicon that is provided over the first bit line layer; a second bit line layer that is provided over the channel layer; a gate electrode that is provided to the sides of the lateral surfaces of an interior of a groove portion formed in the channel layer; and a charge storage layer that is provided between the gate electrode and the channel layer. According to this aspect of the invention, a substrate other than a semiconductor substrate can be used, and therefore the manufacturing costs can be reduced.

A still further aspect of the present invention is a semiconductor device manufacturing method that includes: stacking, over a structure, multiple channel layers sandwiched between bit line layers above and below; forming groove portions in the multiple channel layers so as to reach as far as a lower surface of the lowermost channel layer; forming charge storage layers to the sides of the lateral surfaces of the interiors of the groove portion; and forming gate electrodes inside the groove portions. According to this aspect of the invention, multiple charge storage regions are formed in the charge storage layers provided to the sides of the lateral surfaces of the interiors of the groove portion, and therefore the memory capacity density can be enhanced.

In the above method, the step of forming the gate electrodes may include a step of forming, over the stack structure, word lines connected to multiple gates disposed in the width direction of the groove portions.

In the above method, the step of stacking the multiple channel layers may be implemented by using silicon oxide layers to stick multiple silicon substrates together. In that case, the silicon substrates may be used as channel layers and therefore the performance can be enhanced.

A yet further aspect of the present invention is a semiconductor device manufacturing method that involves: stacking multiple semiconductor layers so as to be insulated from one another; forming source drain regions and channel regions alternately in the lateral direction inside the semiconductor layers; forming groove portions in the multiple semiconductor layers so as to reach as far as a lower surface of the lowermost semiconductor layer; forming charge storage layers to the sides of the lateral surfaces of the interiors of the groove portion; and forming gate electrodes inside the groove portions. According to this aspect of the invention, the memory capacity density can be enhanced.

In the above method, the step of forming the gate electrodes may include a step of forming, over the stack structure, the gate electrodes so that multiple gate electrodes disposed in the width direction of the groove portions are connected.

Preferred embodiments for carrying out the present invention have been set forth above by way of example, but not by way of limiting the invention to these particular embodiments. Many different variations and modifications of the embodiments can be made without departing from the scope and spirit of the invention.

We claim:

1. A semiconductor device comprising:
a stack structure in which multiple channel layers are stacked on a substrate so as to be sandwiched between bit line layers;
a gate electrode that is provided to a side of a lateral surface exposed in a groove portion formed within the stack structure; and
a charge storage layer provided between the gate electrode and the channel layer.

2. The semiconductor device according to claim 1, wherein the groove portion is formed to reach a lower surface of a lowermost channel layer of the stack structure.

3. The semiconductor device according to claim 1, further comprising multiple word lines provided over the stack structure, wherein each of the multiple word lines is connected to multiple gate electrodes disposed in a width direction of the groove portion.

4. The semiconductor device according to claim 3, wherein the multiple word lines are electrically separated from each other.

5. The semiconductor device according to claim 1, wherein the multiple channel layers comprise polysilicon.

6. The semiconductor device according to claim 1, wherein one of the bit line layers between adjacent channel layers among the multiple channel layers is shared by the adjacent channel layers.

7. The semiconductor device according to claim 1, further comprising an insulating layer provided in one of the bit line layers provided between adjacent channel layers among the multiple channel layers so that the one of the bit line layers is divided into portions respectively associated with the adjacent channel layers.

8. The semiconductor device according to claim 1, wherein the charge storage layer comprises a silicon nitride film sandwiched between silicon oxide films.

9. A semiconductor device comprising:
multiple semiconductor layers which have source drain regions and channel regions disposed alternately in a lateral direction and stacked in a longitudinal direction so that the source drain regions and the channel regions are superposed longitudinally and are insulated from each other;
gate electrodes that are provided to sides of the channel regions at a lateral surface of a groove portion formed in the multiple semiconductor layers and extending in the lateral direction;
a charge storage layer that is provided between the channel region and the gate electrode; and
an insulating layer that is provided to the side of the source drain region at the lateral surface of the interior of the groove portion.

10. The semiconductor device according to claim 9, wherein the source drain region and the channel region disposed alternately in the lateral direction constitute a NAND cell.

11. The semiconductor device according to claim 9, wherein the semiconductor layer contains polysilicon.

12. A semiconductor device comprising:
a first bit line layer that is provided over a substrate;
a channel layer containing polysilicon that is provided over the first bit line layer;
a second bit line layer that is provided over the channel layer;
a gate electrode that is provided to the side of the lateral surface of an interior of a groove portion formed in the channel layer; and
a charge storage layer that is provided between the gate electrode and the channel layer.

13. A method for manufacturing a semiconductor device, comprising:
stacking multiple channel layers, sandwiched between bit line layers above and below, over a substrate;
forming a groove portion in the multiple channel layers so as to reach the lower surface of the lowermost channel layer;
forming a charge storage layer to the side of the lateral surface of the groove portion; and
forming a gate electrode inside the groove portion.

14. The method for manufacturing a semiconductor device according to claim 13, wherein forming the gate electrode includes forming over the stack structure multiple word lines that are disposed in the width direction of the groove portion and connected to the gate electrode.

15. The method for manufacturing a semiconductor device according to claim 13, wherein the stacking of the multiple channel layers is implemented by using a silicon oxide layer to stick multiple silicon substrates together.

16. A method for manufacturing a semiconductor device, comprising:
stacking multiple semiconductor layers so as to be insulated from one another;
forming a source drain region and a channel region alternately in the lateral direction inside the semiconductor layer;
forming a groove portion in the multiple semiconductor layers so as to reach as far as the lower surface of the lowermost semiconductor layer;
forming a charge storage layer to the side of the lateral surface of the interior of the groove portion; and
forming a gate electrode inside the groove portion.

17. The method for manufacturing a semiconductor device according to claim 16, wherein forming the gate electrode includes forming, over the stack structure and so as to be connected, multiple gate electrodes that are disposed in the width direction of the groove portion.
